(19) United States
(12) Patent Application Publication
(10) Pub. No.: US 2013/0168724 A1
(43) Pub. Date: Jul. 4, 2013

(54) WARM WHITE LIGHT LED CHIP WITH HIGH BRIGHTNESS AND HIGH COLOR RENDERING

(71) Applicants: Xinshen Xue, Bao'an Shenzhen (CN); Xigang Zhao, Bao'an Shenzhen (CN)

(72) Inventors: Xinshen Xue, Bao'an Shenzhen (CN); Xigang Zhao, Bao'an Shenzhen (CN)

(73) Assignee: CIVILIGHT SHENZHEN SEMICONDUCTOR LIGHTING CO., LTD, Bao'an Shenzhen, Guangdong (CN)

(21) Appl. No.: 13/821,450

(22) PCT Filed: Sep. 7, 2010
(86) PCT No.: PCT/CN2010/076664

§ 371 Date: Mar. 7, 2013

(51) Int. Cl. H01L 33/36

(52) U.S. Cl. CPC H01L 33/36
USPC 257/99

(57) ABSTRACT

A warm white light LED chip with high brightness and high color rendering includes a white light part emitting a white light, a colored light part emitting a colored light with a wavelength of 580 nm-660 nm, an N electrode (8, 294, 394, 494) and a P electrode (7). Connected electrically with the N electrode (8, 294, 394, 494) and the P electrode (7) respectively, the warm white light LED chip directly emits warm white light with a color temperature of 2400K to 3500K and a color rendering index larger than 85. When the chip is lighted, the white light part emits the white light directly, or a blue light part stimulates fluorescent powder to form the white light, and the colored light part emits the colored light with the wavelength of 580 nm-660 nm to compensate the white light, thereby forming a low color temperature light source with high brightness and high color rendering.

### TECHNICAL FIELD

The present invention relates to a semiconductor lighting field, and more particularly, to a white light LED chip with high brightness and high color rendering.

### BACKGROUND

The semiconductor lighting is with the characters of friendly environment, long life, high efficiency, energy-saving, bad environment resistance, simple structure, small volume, light weight, quick response, low work voltage and good safety. So the semiconductor lighting is known as the fourth electric lighting source following the incandescent lamp, fluorescent lamp and energy-saving lamp, or is known as the green lighting source in the 21st century.

The blue light LED chip with fluorescent powder is the mainstream of the white light LED technology. The white light LED technology that the white light is obtain by inverting the light through the fluorescent powder can't achieve purpose of low college temperature and high color rendering because the emission spectrum of fluorescent powder is lack of a red light component. But the people is used to a low temperature (about 3000K) lighting source in the daily life, and the high color rendering lighting source have a potential application prospect in the special lighting environment such as museum, surgical operation room and so on. So it has important significant for developing the low color temperature white light LED with high color rendering.

### SUMMARY

To solve the problem that the present low color temperature lighting source is low brightness and color rendering, the present invention provides warm white light LED chip with high brightness and high color rendering.

The provided warm white light LED chip with high brightness and high color rendering includes a white light part configured to emit a white light, a colored light part configured to emit a colored light with a wavelength of 580 nm-660 nm, an N electrode and a P electrode. The warm white light LED chip directly emits warm white light with a color temperature of 2400K to 3500K and a color rendering index larger than 85 when the N electrode and the P electrode are electrically connected to a power source.

Further, the warm white light LED chip is stimulate to emit the white light directly, or the warm white light LED chip is stimulated to emit blue light and then the blue light stimulates a fluorescent powder to thereby form the white light.

Further, the fluorescent powder is sputtered, absorbed or grown on the surface of the warm white light LED chip with high brightness and high color rendering.

Further, the white light is with a color temperature of 3000K to 10000K.

Further, the colored light with the wavelength of 580 nm-660 nm is red light, yellow light or orange light.

In the present invention, the warm white light LED chip with high brightness and high color rendering includes a white light part and a colored light part. The white light part and the colored light part are grown respectively, so different color lights are emitted in different region of the LED chip. The colored light part emits color light with a wavelength of 580 nm-660 nm which may compensate the white light emitted by the white part. A high brightness, high color rendering and low color temperature lighting source may be formed. Furthermore, the manufacturing method of the warm white light LED chip with high brightness and high color rendering is simple and low cost.

The warm white light LED chip with high brightness and high color rendering of the present invention may effectively improve the luminous efficacy of the LED lamp. When the color rendering index is larger than 90, the luminous efficacy of the warm white light LED chip of the present invention is larger than 100 μm/w and is improved 25% compared to the luminous efficacy of the present LED chip. The warm white light LED chip with high brightness and high color rendering of the present invention is designed elaborately. So the LED chip of the present invention may be used to manufacture the middle or large power LED larger than 0.1 W. The LED chip of the present invention may improve the reliability and conformity of the LED product. The LED chip of the present invention may be mass-produced through the machine, so the producing efficiency may be greatly improved and the cost of the product is decreased. The LED chip of the present invention may effectively control the amount of the fluorescent glue. The luminous efficacy of the LED product is improved and the cost of LED product is saved. The special design of the LED chip of the present invention may achieve the warm white light effect by using a single LED chip, so the increasing cost and decreasing reliability problem caused by using other fluorescent powder may be avoided.

### BRIEF DESCRIPTION OF THE DRAWINGS

FIG. 1 is a sectional view of the warm white light LED chip with high brightness and high color rendering according to a first embodiment of the present invention.

FIG. 2 is a top view of the warm white light LED chip with high brightness and high color rendering according to the first embodiment of the present invention.

FIG. 3 is a sectional view of the warm white light LED chip with high brightness and high color rendering according to a second embodiment of the present invention.

FIG. 4 is a sectional view of the warm white light LED chip with high brightness and high color rendering according to a third embodiment of the present invention.

FIG. 5 is a sectional view of the warm white light LED chip with high brightness and high color rendering according to a fourth embodiment of the present invention.

### DETAILED DESCRIPTION OF THE PREFERRED EMBODIMENTS

For a clear purpose, technology solution and advantage of the present invention, a detailed description of embodiments of the invention is displayed hereafter in connection with the accompanying drawings. It should be understood that the detailed embodiments according to the present invention are provided for explanation only, and not for the purpose of limiting the invention.

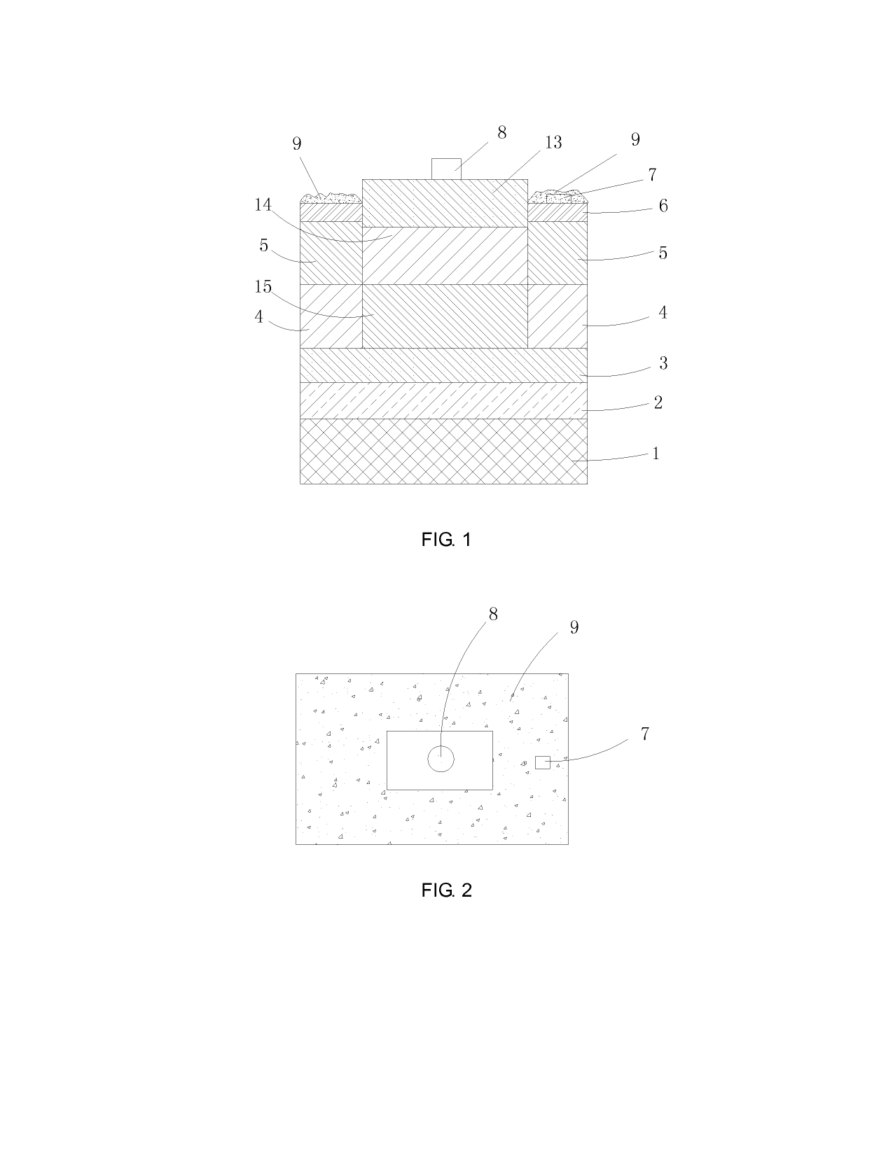

Referring to FIGS. 1 and 2, FIG. 1 is a sectional view of the warm white light LED chip with high brightness and high color rendering according to the first embodiment of the present invention. A basic epitaxial structure of the white light part for the warm white light LED chip with high brightness and high color rendering is formed in a metal organic chemical vapor deposited (MOCVD) wafer furnace. Form the bottom to the top, the basic epitaxial structure of the white part successively includes a substrate 1, a buffer layer 2, a first N layer 4, a first quantum well layer 14, a first P layer 5, and a current diffusion layer 6. And a fluorescent powder layer 9 is formed on a top surface of the current diffusion layer 6 through a sputtering or an absorption method. In the middle part of the epitaxial structure of the white light part, starting from the first N layer of the epitaxial structure a second P layer 15, a second quantum well layer 14, and a second N layer 13 are formed successively through a regrowth method to form a color light part. An N electrode 8 is disposed on the second N layer 13 of the color light part and a P electrode 7 is disposed on the current diffusion layer 6. The N electrode 8 and the P electrode 7 are processed. Finally, dicing, testing and selecting of a crude LED wafer are performed, and the required LED chip is obtained.

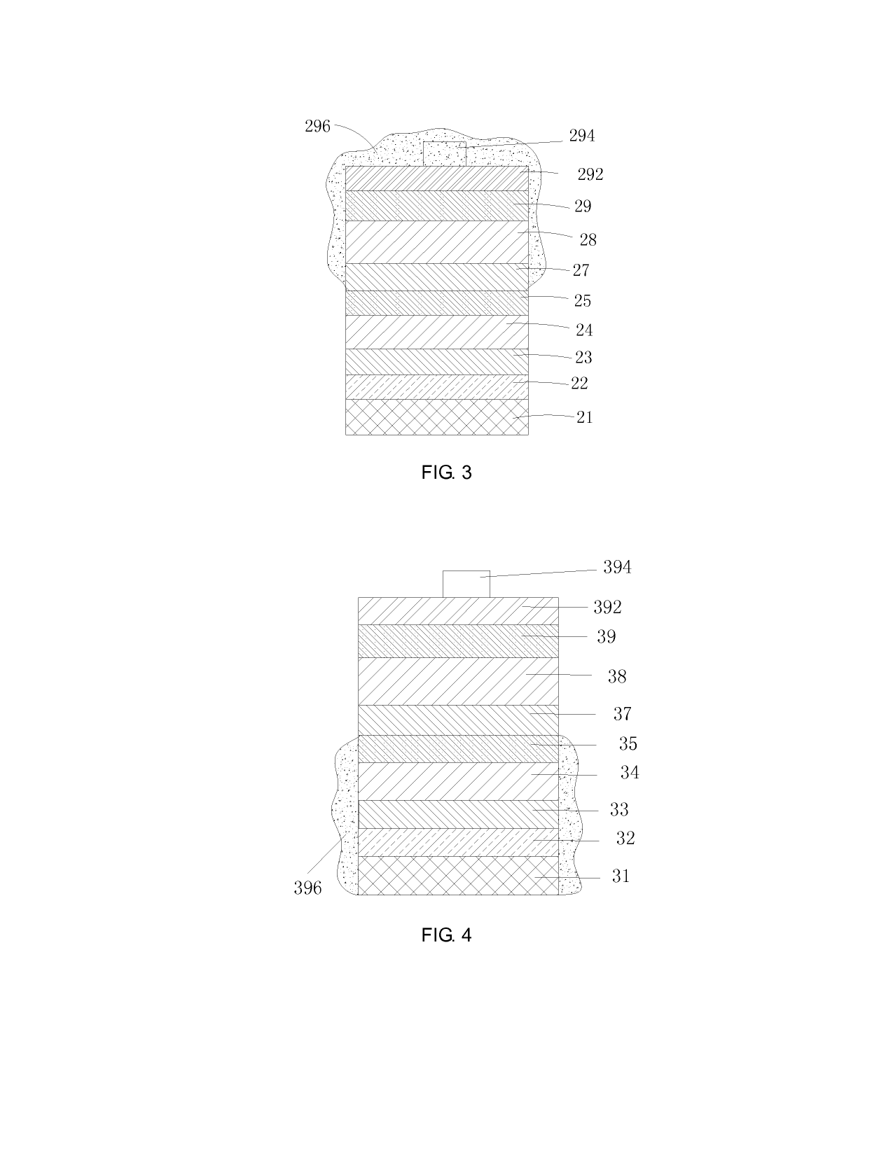

Referring to FIG. 3, FIG. 3 is a sectional view of the warm white light LED chip with high brightness and high color rendering according to the second embodiment of the present invention. A substrate 21, a buffer layer 22, a second P layer 23, a second quantum well layer 24, and a second N layer 25 are successively formed to formed a basic epitaxial structure of a color light part for the warm white light LED chip with high brightness and high color rendering in a metal organic chemical vapor deposited (MOCVD) wafer furnace. Above the color light part, a first P layer 27, a first quantum well layer 28, a first N layer 29, and a current diffusion layer 292 are successively grown through a regrowth method, and a fluorescent powder layer 296 is formed on the first P layer 27, the first quantum well layer 28, the first N layer 29, and the current diffusion layer 292 through a sputtering or a absorption method, to thereby form a white light part. An N electrode 294 is disposed on the current diffusion layer 292 and a P electrode is disposed on the substrate 21. The N electrode 292 and the P electrode are processed. Finally, dicing, testing and selecting of a crude LED wafer are performed, and the required LED chip is obtained.

Referring to FIG. 4, FIG. 4 is a sectional view of the warm white light LED chip with high brightness and high color rendering according to the third embodiment of the present invention. A substrate 31, a buffer layer 32, a first P layer 33, a first quantum well layer 34, and a first N layer 35 are successively formed to form a basic epitaxial structure of a white light part for the warm white light LED chip with high brightness and high color rendering in a metal organic chemical vapor deposited (MOCVD) wafer furnace. And a fluorescent powder layer 396 is formed on the side surface of the substrate 31, the buffer layer 32, the first P layer 33 and the first quantum well layer 34, a first N layer 35 through a sputtering or an absorption method. A second P layer 37, a second quantum well layer 38, a second N layer 39 and a current diffusion layer 392 are successively grown on the basic epitaxial structure of the white light part through a regrowth method to form a color light part. An N electrode 394 is disposed on the current diffusion layer 392 and a P electrode is disposed on the substrate 31. The N electrode 394 and the P electrode are processed. Finally, dicing, testing and selecting of a crude LED wafer are performed, and the required LED chip is obtained.

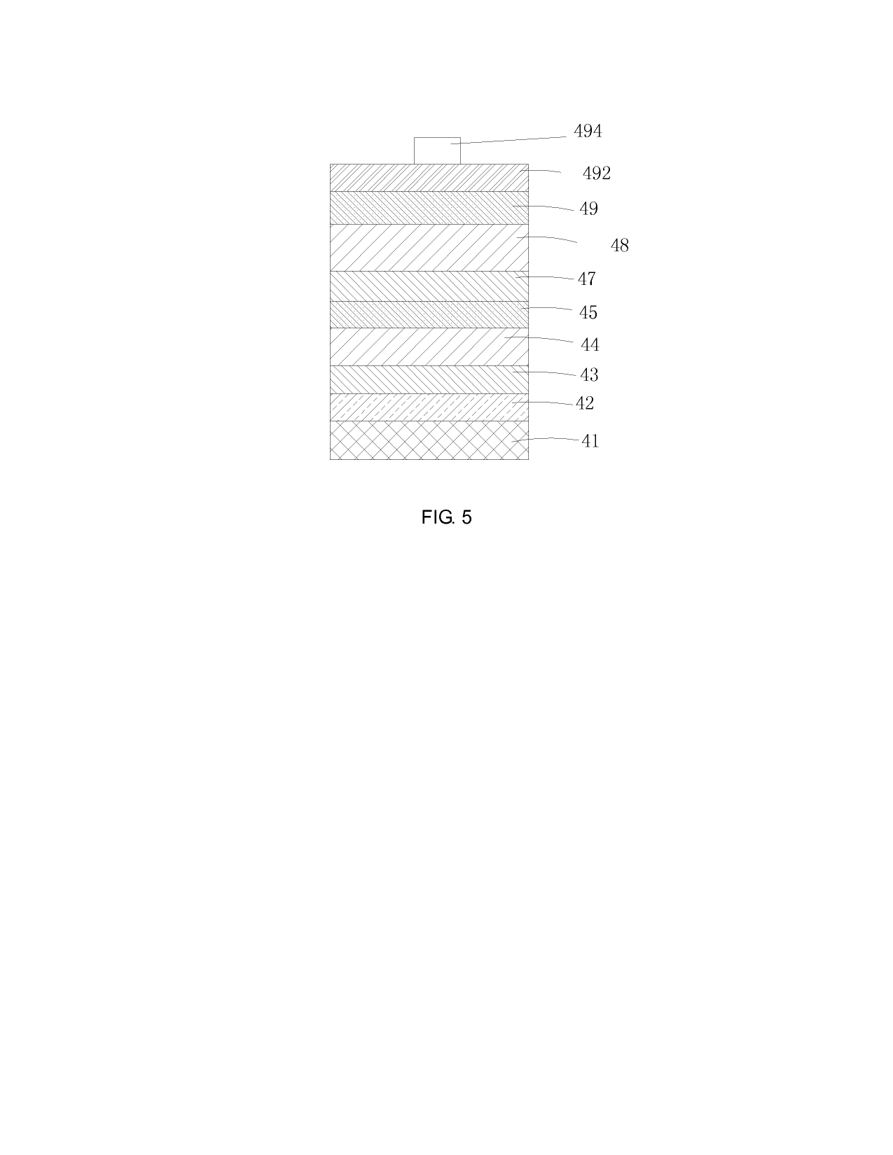

Referring to FIG. 5, FIG. 5 is a sectional view of the warm white light LED chip with high brightness and high color rendering according to the fourth embodiment of the present invention. A substrate 41, a buffer layer 42, a second P layer 43, a second quantum well layer 44, and a second N layer 45 are successively formed to formed a basic epitaxial structure of a color light part for the warm white light LED chip with high brightness and high color rendering in a metal organic chemical vapor deposited (MOCVD) wafer furnace. Above the color light part, a first P layer 47, a first quantum well layer 48, a first N layer 49, and a current diffusion layer 492 are successively grown through a regrowth method to thereby form a white light part. An N electrode 494 is disposed on the current diffusion layer 492 and a P electrode is disposed on the substrate 41. The N electrode 492 and the P electrode are processed. Finally, dicing, testing and selecting of a crude LED wafer, and the required LED chip is obtained.

In above embodiments, the material of the substrate may be sapphire, SiC or Si.

In above embodiments, the thickness of the fluorescent powder layer of the white light part and the proportion of different color fluorescent powders in the fluorescent powder layer may be adjusted according to an actual requirement, so the requirement of different color temperature may be achieved.

For the white light part and the color light part, the white light may be formed firstly and then the color light part is formed, or the color light may be formed firstly and then the white light part is formed.

The white light part may stimulate the fluorescent powder to form the white light. The color temperature of the white light is from 3000K to 10000K. The colored light part emits color light with a wavelength of 580 nm-660 nm to compensate the white light emitted by the white part. A high brightness, high color rendering and low color temperature lighting source may be formed. The colored light with the wavelength of 580 nm-660 nm is red light, yellow light or orange light.

The warm white light LED chip with high brightness and high color rendering according to some embodiments of the present invention directly emits warm white light with a color temperature of 2400K to 3500K and a color rendering index larger than 85 if the N electrode and the P electrode are connected to a power source. The warm white light LED chip includes a white light part and a color light part. The white light part and the colored light part are grown respectively, so different color lights are emitted in different region of the LED chip. The white light part emits the white light directly, or the colored light part emits a blue light and the blue light stimulates a fluorescent powder on the surface of the color light part to form the white light indirectly.

The white light part emits the white light directly, or the colored light part emits a blue light and the blue light stimulates a fluorescent powder to form the white light. Besides, the colored light part emits color light with a wavelength of 580 nm-660 nm to compensate the white light, so a high brightness, high color rendering and low color temperature lighting source may be formed. Furthermore, the manufacturing method of the warm white light LED chip with high brightness and high color rendering is simple and low cost.

The warm white light LED chip with high brightness and high color rendering of the present invention may effectively improve the luminous efficacy of the LED lamp. When the color rendering index is larger than 90, the luminous efficacy of the warm white light LED chip of the present invention is larger than 1001 m/w and is improved 25% compared to the luminous efficacy of the present LED chip. The warm white light LED chip with high brightness and high color rendering of the present invention is designed elaborately. So the LED chip of the present invention may be used to manufacture the middle or large power LED larger than 0.1 W. The LED chip of the present invention may improve the reliability and conformity of the LED product. The LED chip of the present invention may be mass-produced through the machine, so the producing efficiency may be greatly improved and the cost of the product is decreased. The LED chip of the present invention may effectively control the amount of the fluorescent glue. The luminous efficacy of the LED product is improved and the cost of LED product is saved. The special design of the LED chip of the present invention may achieve the warm white light effect by using a single LED chip, so the increasing cost and decreasing reliability problem caused by using other fluorescent powder may be avoided.

A manufacturing for the warm white light LED chip with high brightness and high color rendering is also provided. The method comprises the steps of: growing a white light part and a color light part and forming an N electrode and a P electrode above the white light part and the color light part.

For a further development of the invention, in some embodiment, the color light part is formed by growing a blue light part configured to emit a blue light and coated with a fluorescent powder layer. The fluorescent powder is sputtered, absorbed or grown on the blue light part.

For a further development of the invention, in some embodiment, the white light may be formed firstly and then the color light part is formed, or the color light may be formed firstly and then the white light part is formed.

The embodiments mentioned above is the best mode for the present invention, the present invention is not limited by the above embodiment. It should be understood that various alternatives to the embodiments of the invention described herein may be employed in practicing the invention.

What is claimed is:

1. A warm white light LED chip with high brightness and high color rendering comprising:
a white light part configured to emit a white light;
a colored light part configured to emit a colored light with a wavelength of 580 nm-660 nm;
an N electrode; and
a P electrode,
wherein the warm white light LED chip directly emits warm white light with a color temperature of 2400K to 3500K and a color rendering index larger than 85 when the N electrode and the P electrode are electrically connected to a power source.

2. The warm white light LED chip with high brightness and high color rendering of claim 1, wherein the warm white light LED chip is excited to emit the white light directly, or the warm white light LED chip is excited to emit blue light and then the blue light stimulates a fluorescent powder to thereby form the white light.

3. The warm white light LED chip with high brightness and high color rendering of claim 2, wherein the fluorescent powder is sputtered, absorbed or grown on a surface of the warm white light LED chip with high brightness and high color rendering.

4. The warm white light LED chip with high brightness and high color rendering of claim 1, wherein the white light is with a color temperature of 3000K to 10000K.

5. The warm white light LED chip with high brightness and high color rendering of claim 1, wherein the colored light with the wavelength of 580 nm-660 nm is red light, yellow light or orange light.
